(19) United States
(12) Patent Application Publication
(10) Pub. No.: US 2025/0359410 A1
(43) Pub. Date: Nov. 20, 2025

(54) DISPLAY DEVICE AND ELECTRONIC DEVICE

(71) Applicant: Samsung Display Co., LTD., Yongin-si (KR)

(72) Inventors: Ki Nyeng KANG, Yongin-si (KR); Ock Soo SON, Yongin-si (KR); Jong Hyuk KANG, Yongin-si (KR); Sung Hoon KIM, Yongin-si (KR); Keun Kyu SONG, Yongin-si (KR)

(73) Assignee: Samsung Display Co., LTD., Yongin-si (KR)

(21) Appl. No.: 19/213,257

(22) Filed: May 20, 2025

(30) Foreign Application Priority Data
May 20, 2024 (KR) 10-2024-0065079

(51) Int. Cl. H10H 29/37

(52) U.S. Cl. CPC H10H 29/37

(57) ABSTRACT

A display device includes a bank surrounding an emission area, a first electrode and a second electrode spaced apart from each other in the emission area, and light emitting elements disposed between the first electrode and the second electrode, and in case that a diameter of each of the light emitting elements is α, a maximum distance between the light emitting elements in a first direction is about 25α or less, and a maximum distance between a light emitting element closest to the bank among the light emitting elements in the first direction and the bank is about 12.5α or less.

### CROSS-REFERENCE TO RELATED APPLICATION

The application claims priority to and benefits of Korean Patent Application No. 10-2024-0065079 under 35 U.S.C. § 119, filed on May 20, 2024, the entire contents of which are incorporated herein by reference.

### BACKGROUND

### 1. Technical Field

Embodiments relate to a display device and an electronic device.

### 2. Description of the Related Art

In recent years, as interest in information displays has increased, research and development on display devices have been continuously conducted.

### SUMMARY

Embodiments provide a display device with improved reliability.

Objects of the disclosure are not limited to the above-described object, and other technical objects not mentioned will be clearly understood by those skilled in the art from the following description.

According to an embodiment, a display device according to embodiments may include a bank surrounding an emission area; a first electrode and a second electrode spaced apart from each other in the emission area; and light emitting elements disposed between the first electrode and the second electrode. In case that a diameter of each of the light emitting elements is α, a maximum distance between the light emitting elements in a first direction may be about 25α or less, and a maximum distance between a light emitting element closest to the bank among the light emitting elements in the first direction and the bank may be about 12.5α or less.

The α may be about 0.5 μm or less.

The maximum distance between the light emitting elements in the first direction may be about 4 μm or more.

The bank may extend in a second direction intersecting the first direction and may include a first extension and a second extension spaced apart from each other.

A maximum distance between a light emitting element closest to the first extension among the light emitting elements in the first direction and the first extension may be about 12.5α or less.

A maximum distance between a light emitting element closest to the second extension among the light emitting elements in the first direction and the second extension may be about 12.5α or less.

The first electrode and the second electrode may be spaced apart from each other in a second direction intersecting the first direction.

First end portions of the light emitting elements may face the first electrode, and second end portions of the light emitting elements may face the second electrode.

The display device may further include a first connection electrode and a second connection electrode disposed on the light emitting elements.

The first connection electrode may be electrically connected to the first end portions of the light emitting elements, and the second connection electrode may be electrically connected to the second end portions of the light emitting elements.

To achieve the above object, a display device according to embodiments may include a bank surrounding an emission area; a first electrode and a second electrode spaced apart from each other in the emission area; and light emitting elements disposed between the first electrode and the second electrode. A maximum number of light emitting elements disposed in the emission area may satisfy Equation 1 below.

2γ+nα+(n−1)β=δ [Equation 1]

Here, α may be a diameter of each of the light emitting elements, β may be a maximum distance between the light emitting elements in a first direction, γ may be a maximum distance between a light emitting element closest to the bank among the light emitting elements in the first direction and the bank, n may be a maximum number of light emitting elements disposed in the emission area, and δ may be a maximum length of the emission area in the first direction.

The β may be about 25α or less.

The γ may be about 12.5α or less.

The α may be about 0.5 μm or less.

The β may be about 4 μm or more.

The first electrode and the second electrode may be spaced apart from each other in a second direction intersecting the first direction.

First end portions of the light emitting elements may face the first electrode, and second end portions of the light emitting elements may face the second electrode.

The display device may further include a first connection electrode and a second connection electrode disposed on the light emitting elements.

The display device may further include an insulating pattern disposed between the light emitting elements and the first connection electrode and/or the second connection electrode.

The first connection electrode may be electrically connected to the first end portions of the light emitting elements exposed by the insulating pattern, and the second connection electrode may be electrically connected to the second end portions of the light emitting elements exposed by the insulating pattern.

According to an embodiment, an electronic device according to embodiments may include a processor to provide input image data; and a display device to display an image based on the input image data, the display device including sub-pixel areas, wherein the display device may include a bank surrounding an emission area; a first electrode and a second electrode spaced apart from each other in the emission area; and light emitting elements disposed between the first electrode and the second electrode. In case that a diameter of each of the light emitting elements is α, a maximum distance between the light emitting elements in a first direction may be about 25α or less, and a maximum distance between a light emitting element closest to the bank among the light emitting elements in the first direction and the bank may be about 12.5α or less.

Specific details of other embodiments are included in the detailed description and accompanying drawings.

### BRIEF DESCRIPTION OF THE DRAWINGS

The accompanying drawings, which are included to provide a further understanding of the inventive concepts, and are incorporated in and constitute a part of this specification, illustrate embodiments of the inventive concepts, and, together with the description, serve to explain principles of the inventive concepts.

FIG. 1 is a schematic perspective view illustrating a light emitting element according to an embodiment.

FIG. 2 is a schematic cross-sectional view illustrating the light emitting element according to an embodiment.

FIG. 3 is a schematic plan view illustrating a display device according to an embodiment.

FIG. 4 is a schematic diagram of an equivalent circuit of a pixel according to an embodiment.

FIGS. 5 and 6 are schematic plan views illustrating pixels according to embodiments.

FIG. 7 is a schematic plan view for explaining an arrangement of light emitting elements according to an embodiment.

FIG. 8 is a schematic cross-sectional view taken along line A-A′ in FIG. 5.

FIG. 9 is a schematic cross-sectional view taken along line B-B′ in FIG. 5.

FIG. 10 is a schematic cross-sectional view taken along line C-C′ in FIG. 6.

FIG. 11 is a schematic cross-sectional view taken along line D-D′ in FIG. 6.

FIG. 12 is a schematic cross-sectional view illustrating first to third pixels according to an embodiment.

FIG. 13 is a schematic cross-sectional view of a pixel according to an embodiment.

FIG. 14 is a schematic block diagram illustrating an electronic device including a display device in accordance with an embodiment.

FIG. 15 is a schematic diagram illustrating an example where the electronic device of FIG. 14 is a smartphone.

FIG. 16 is a schematic diagram illustrating an example where the electronic device of FIG. 14 is a tablet computer.

### DETAILED DESCRIPTION OF THE ILLUSTRATED EMBODIMENTS

Advantages and features of the disclosure, and methods for accomplishing the same will be more clearly understood from embodiments described below with reference to the accompanying drawings. However, the disclosure is not limited to the following embodiments but may be implemented in various different forms. The embodiments are provided only to complete the disclosure and to fully inform a person having ordinary skill in the art to which the disclosure pertains the scope of the disclosure. The disclosure is only defined by the scope of the appended claims.

The terms used in the disclosure are for describing embodiments and are not intended to limit the disclosure. In the disclosure, the singular forms are intended to include the plural forms as well, unless the context clearly indicates otherwise. As used in the disclosure, the term “comprises” and/or “comprising” does not exclude the presence or addition of one or more other components, steps, operations and/or elements to the mentioned component, step, operation and/or element.

In addition, the term “connection” may include not only electrical connection but also physical connection, may include direct connection as well as indirect connection through other components, or may include an integral connection or a non-integral connection.

A phrase “an element or a layer is disposed on another element or another layer” may refer to that the element may be disposed directly on another element and/or the element may be disposed indirectly on another element via another element or another layer. Like reference numerals generally refer to like elements throughout the disclosure.

Although the terms first, second, etc. may be used herein to describe various components, these components should not be limited by these terms. These terms are only used to distinguish one component from another component. Thus, a first component discussed below may be a second component in the technical spirit of the disclosure.

Hereinafter, embodiments will be described in more detail with reference to the accompanying drawings.

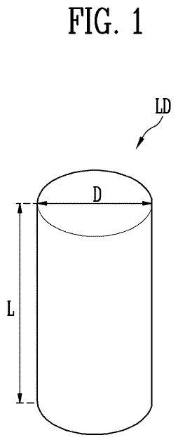

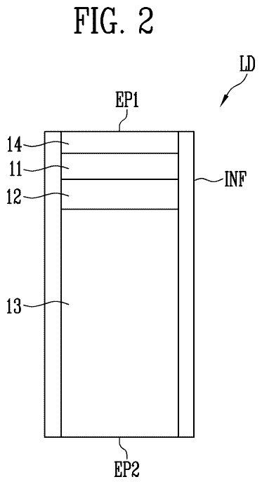

FIG. 1 is a schematic perspective view illustrating a light emitting element according to an embodiment. FIG. 2 is a schematic cross-sectional view illustrating the light emitting element according to an embodiment. FIGS. 1 and 2 show a light emitting element LD having a column shape or a pillar shape, but the type and/or shape of the light emitting element LD is not limited thereto.

Referring to FIGS. 1 and 2, the light emitting element LD may include a first semiconductor layer 11, an active layer 12, a second semiconductor layer 13, and/or an electrode layer 14.

The light emitting element LD may be formed in a column shape extending in a direction. The light emitting element LD may have a first end portion EP1 and a second end portion EP2. One of the first and second semiconductor layers 11 and 13 may be disposed at the first end portion EP1 of the light emitting element LD. The other of the first and second semiconductor layers 11 and 13 may be disposed at the second end portion EP2 of the light emitting element LD. For example, the first semiconductor layer 11 may be disposed at the first end portion EP1 of the light emitting element LD, and the second semiconductor layer 13 may be disposed at the second end portion EP2 of the light emitting element LD.

According to an embodiment, the light emitting element LD may be a light emitting element manufactured in a column shape through an etching method or the like. In the present disclosure, the column shape may include a rod-like shape or a bar-like shape with an aspect ratio greater than 1, such as a circular column or a polygonal column, and the shape of the cross section is not limited.

The light emitting element LD may have a size as small as nanometer scale to micrometer scale. The light emitting element LD may have a diameter D (or width) and/or length L in the nanometer scale to micrometer scale range. As an example, the diameter D of the light emitting element LD may be about 0.5 μm or less. The length L of the light emitting element LD may be about 10 μm or less. The length L of the light emitting element LD may be about 5 μm or less. However, the size of the light emitting element LD is not limited thereto. The size of the light emitting element LD may be variously changed according to design conditions of various devices using the light emitting device including the light emitting element LD as a light source, for example, a display device and the like.

The first semiconductor layer 11 may be a semiconductor layer of a first conductivity type. For example, the first semiconductor layer 11 may include a p-type semiconductor layer. As an example, the first semiconductor layer 11 may include a p-type semiconductor layer including at least one of InAlGaN, GaN, AlGaN, InGaN, and AlN and doped with a first conductivity type dopant such as Mg. However, the material constituting (or forming) the first semiconductor layer 11 is not limited thereto, and various other materials may constitute (or form) the first semiconductor layer 11.

The active layer 12 may be disposed between the first semiconductor layer 11 and the second semiconductor layer 13. The active layer 12 may include any one structure of a single well structure, a multi-well structure, a single quantum well structure, a multi quantum well (MQW) structure, a quantum dot structure, or a quantum wire structure, but embodiments are not limited thereto. The active layer 12 may include GaN, InGaN, InAlGaN, AlGaN, AlN, or the like, and various other materials may constitute (or form) the active layer 12. In case that a voltage higher than a threshold voltage is applied to end portions (e.g., opposite end portions) of the light emitting element LD, electron-hole pairs may be combined in the active layer 12 and the light emitting element LD may emit light. By controlling the light emission of the light emitting element LD using this principle, the light emitting element LD may be used as a light source for various light emitting devices, including pixels of a display device.

The second semiconductor layer 13 may be disposed on the active layer 12 and may include a different type of semiconductor layer than the first semiconductor layer 11. The second semiconductor layer 13 may include an n-type semiconductor layer. As an example, the second semiconductor layer 13 may include an n-type semiconductor layer including any one of InAlGaN, GaN, AlGaN, InGaN, and AlN and doped with a second conductivity type dopant such as Si, Ge, or Sn. However, the material constituting (or forming) the second semiconductor layer 13 is not limited thereto, and various other materials may constitute (or form) the second semiconductor layer 13.

The electrode layer 14 may be disposed on the first end portion EP1 and/or the second end portion EP2 of the light emitting element LD. In FIG. 2, a case where the electrode layer 14 is formed on the first semiconductor layer 11 is shown as an example, but embodiments are not limited thereto. For example, a separate electrode layer may be further disposed on the second semiconductor layer 13.

The electrode layer 14 may include transparent metal or transparent metal oxide. As an example, the electrode layer 14 may include at least one of indium tin oxide (ITO), indium zinc oxide (IZO), and zinc tin oxide (ZTO), but embodiments are not limited thereto. In case that the electrode layer 14 is made of transparent metal or transparent metal oxide, light generated in the active layer 12 of the light emitting element LD may pass through the electrode layer 14 and may be emitted to the outside of the light emitting element LD.

An insulating film INF may be disposed on a surface of the light emitting element LD. The insulating film INF may be disposed (e.g., directly disposed) on surfaces of the first semiconductor layer 11, the active layer 12, the second semiconductor layer 13, and/or the electrode layer 14. The insulating film INF may expose the first and second end portions EP1 and EP2 of the light emitting element LD having different polarities.

The insulating film INF may prevent an electrical short circuit that occurs in case that the active layer 12 is in contact with conductive materials other than the first and second semiconductor layers 11 and 13. The insulating film INF may improve the lifespan and light emitting efficiency of light emitting elements LD by minimizing surface defects of the light emitting elements LD.

The insulating film INF may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). For example, the insulating film INF may be composed of a double layer, and layers constituting (or forming) the double layer may include different materials. As an example, the insulating film INF may be composed of a double layer made of aluminum oxide (AlOₓ) and silicon oxide (SiOₓ), but embodiments are not limited thereto. In another example, the insulating film INF may be omitted.

A light emitting device including the light emitting element LD described above may be used in various types of devices that require a light source, including a display device. For example, the light emitting elements LD may be disposed in each pixel of a display panel, and the light emitting elements LD may be used as a light source for each pixel. However, the application field of the light emitting element LD is not limited to the examples described above. For example, the light emitting element LD may also be used in other types of devices that require a light source, such as a lighting device.

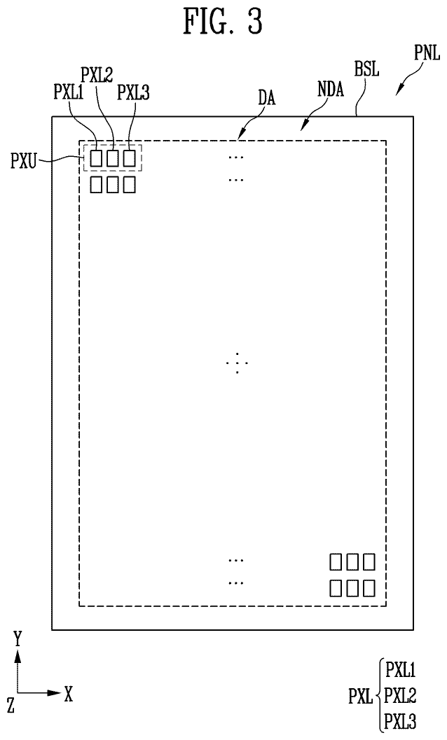

FIG. 3 is a schematic plan view illustrating a display device according to an embodiment.

FIG. 3 shows an example of an electronic device that uses the light emitting element LD described in the embodiments of FIGS. 1 and 2 as a light source, and shows a display device, e.g., a display panel PNL included in the display device.

For convenience of description, FIG. 3 briefly shows a structure of the display panel PNL centered on a display area DA. However, according to embodiments, at least one driving circuit unit (for example, at least one of a scan driver and a data driver), wirings, and/or pads may be further disposed on the display panel PNL.

Referring to FIG. 3, the display panel PNL and a base layer BSL for forming the display panel PNL may include a display area DA for displaying an image and a non-display area NDA that is an area other than the display area DA. The display area DA may constitute (or form) a screen on which an image is displayed, and the non-display area NDA may be the remaining area other than the display area DA.

A pixel unit PXU may be disposed in the display area DA. The pixel unit PXU may include a first pixel PXL1, a second pixel PXL2, and/or a third pixel PXL3. Hereinafter, in case that at least one pixel among the first pixel PXL1, the second pixel PXL2, and the third pixel PXL3 is arbitrarily referred to, or two or more types of pixels are comprehensively referred to, they may be referred to as “pixel PXL” or “pixels PXL”.

Pixels PXL may be arranged regularly according to an arrangement structure such as stripe or PENTILE™. However, the arrangement structure of the pixels PXL is not limited thereto, and the pixels PXL may be arranged in the display area DA in various structures and/or methods.

According to an embodiment, two or more types of pixels PXL that emit light of different colors may be disposed in the display area DA. As an example, first pixels PXL1 emitting light of a first color, second pixels PXL2 emitting light of a second color, and third pixels PXL3 emitting light of a third color may be arranged in the display area DA. At least one first pixel PXL1, second pixel PXL2, and third pixel PXL3 disposed adjacent to each other may form a pixel unit (e.g., single pixel unit) PXU capable of emitting light of various colors. For example, each of the first pixel PXL1, the second pixel PXL2, and the third pixel PXL3 may be a pixel that emits light of a selected color. According to an embodiment, the first pixel PXL1 may be a red pixel that emits red light, the second pixel PXL2 may be a green pixel that emits green light, and the third pixel PXL3 may be a blue pixel that emits blue light, but embodiments are not limited thereto.

In an embodiment, the first pixel PXL1, the second pixel PXL2, and the third pixel PXL3 may include light emitting elements that emit light of the same color. For example, color conversion layers and/or color filter layers of different colors may be disposed on the light emitting elements, so that light of the first color, second color, and third color may be emitted, respectively. In another embodiment, the first pixel PXL1, the second pixel PXL2, and the third pixel PXL3 may include a light emitting element of the first color, a light emitting element of the second color, and a light emitting element of the third color as light sources, so that light of the first color, second color, and third color may be emitted, respectively. However, the color, type, and/or number of pixels PXL constituting (or forming) the pixel unit PXU are not limited. The color of light emitted by each pixel PXL may be changed in various ways.

The pixel PXL may include at least one light source driven by a selected control signal (for example, a scan signal and a data signal) and/or a selected power source (for example, a first power source and a second power source). In an embodiment, the light source may include at least one light emitting element LD according to any one of the embodiments of FIGS. 1 and 2, for example, an ultra-small column-shaped light emitting element LD having a size as small as nanometer scale to micrometer scale. However, embodiments are not limited thereto, and various types of light emitting elements LD may be used as light sources of the pixels PXL.

In an embodiment, each pixel PXL may be composed of an active type pixel. However, the type, structure, and/or driving method of the pixels PXL that are applicable to the display device are not limited. For example, each pixel PXL may constitute (or form) a pixel of a passive or active type light emitting display device having various structures and/or driving methods.

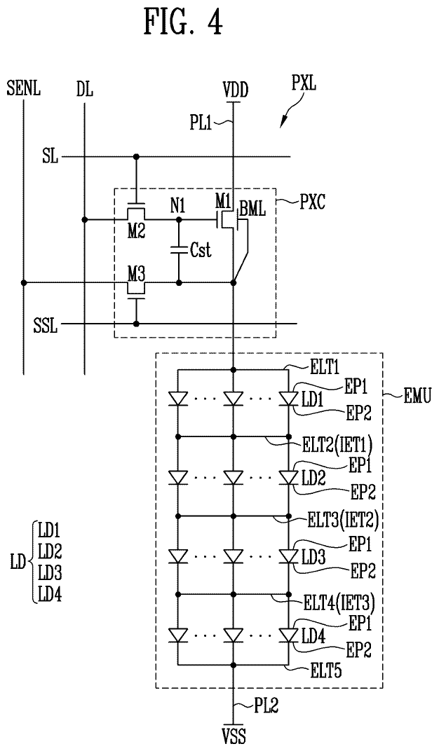

FIG. 4 is a schematic diagram of an equivalent circuit of a pixel according to an embodiment.

The pixel PXL shown in FIG. 4 may be any one of the first pixel PXL1, the second pixel PXL2, and the third pixel PXL3 included in the display panel PNL of FIG. 3. The first pixel PXL1, the second pixel PXL2, and the third pixel PXL3 may have substantially the same or similar structures.

Referring to FIG. 4, the pixel PXL may further include an emission unit EMU for generating light with a luminance corresponding to a data signal, and a pixel circuit PXC for driving the emission unit EMU.

The pixel circuit PXC may be connected between a first power source VDD and the emission unit EMU. The pixel circuit PXC may be connected to a scan line SL and a data line DL of a corresponding pixel PXL and may control the operation of the emission unit EMU in response to a scan signal and a data signal supplied from the scan line SL and the data line DL. The pixel circuit PXC may be further selectively connected to a sensing signal line SSL and a sensing line SENL.

The pixel circuit PXC may include at least one transistor and capacitor. For example, the pixel circuit PXC may include a first transistor M1, a second transistor M2, a third transistor M3, and a storage capacitor Cst.

The first transistor M1 may be connected between the first power source VDD and a first connection electrode ELT1. A gate electrode of the first transistor M1 may be connected to a first node N1. The first transistor M1 may control a driving current supplied to the emission unit EMU in response to a voltage of the first node N1. The first transistor M1 may be a driving transistor that controls the driving current of the pixel PXL.

In an embodiment, the first transistor M1 may optionally include a lower conductive layer BML (also referred to as “a lower electrode”, “a back gate electrode”, or “a lower light blocking layer”). The gate electrode and the lower conductive layer BML of the first transistor M1 may overlap each other with an insulating layer interposed between the gate electrode and the lower conductive layer BML. In an embodiment, the lower conductive layer BML may be connected to an electrode of the first transistor M1, for example, a source electrode or a drain electrode.

In case that the first transistor M1 includes the lower conductive layer BML, back-biasing technology (or synchronization technology) that moves a threshold voltage of the first transistor M1 in a negative or positive direction by applying a back-biasing voltage to the lower conductive layer BML of the first transistor M1 in case that the pixel PXL is driven may be applied. As an example, the threshold voltage of the first transistor M1 may be moved in the negative or positive direction by applying source-sink technology in which the lower conductive layer BML is connected to the source electrode of the first transistor M1. In case that the lower conductive layer BML is disposed below a semiconductor pattern constituting (or forming) a channel of the first transistor M1, the lower conductive layer BML may function as a light blocking pattern and may stabilize the operating characteristics of the first transistor M1. However, the function and/or utilization method of the lower conductive layer BML is not limited thereto.

The second transistor M2 may be connected between the data line DL and the first node N1. For example, a gate electrode of the second transistor M2 may be connected to the scan line SL. The second transistor M2 may be turned on in case that the scan signal of a gate-on voltage (for example, a high level voltage) is supplied from the scan line SL to connect the data line DL and the first node N1.

For each frame period, the data signal of a corresponding frame may be supplied to the data line DL. The data signal may be transmitted to the first node N1 through the second transistor M2 that is turned on in case that the scan signal of the gate-on voltage is supplied. The second transistor M2 may be a switching transistor for transmitting each data signal to the inside of the pixel PXL.

An electrode of the storage capacitor Cst may be connected to the first node N1, and another electrode may be connected to a second electrode of the first transistor M1. The storage capacitor Cst may be charged with a voltage corresponding to the data signal supplied to the first node N1 during each frame period.

The third transistor M3 may be connected between the first connection electrode ELT1 (or the second electrode of the first transistor M1) and the sensing line SENL. A gate electrode of the third transistor M3 may be connected to the sensing signal line SSL. The third transistor M3 may transmit a voltage value applied to the first connection electrode ELT1 to the sensing line SENL according to a sensing signal supplied to the sensing signal line SSL. The voltage value transmitted through the sensing line SENL may be included to an external circuit (for example, a timing controller). The external circuit may extract characteristic information (for example, a threshold voltage of the first transistor M1 and the like) of each pixel PXL based on the provided voltage value. The extracted characteristic information may be used to transform image data so that characteristic deviations between the pixels PXL may be compensated.

In FIG. 4, transistors included in the pixel circuit PXC are all shown as n-type transistors, but embodiments are not limited thereto. For example, at least one of the first, second, and third transistors M1, M2, and M3 may be modified to a p-type transistor.

The structure and driving method of the pixel PXL may be changed in various ways. For example, the pixel circuit PXC may be composed of pixel circuits with various structures and/or driving methods, in addition to the embodiment shown in FIG. 4.

As an example, the pixel circuit PXC may not include the third transistor M3. The pixel circuit PXC may further include other circuit elements such as a compensation transistor for compensating for the threshold voltage of the first transistor M1, an initialization transistor for initializing the voltage of the first node N1 and/or the first connection electrode ELT1, an emission control transistor for controlling a period during which the driving current is supplied to the emission unit EMU, and/or a boosting capacitor for boosting the voltage of the first node N1.

The emission unit EMU may include at least one light emitting element LD, for example, light emitting elements LD connected between the first power source VDD and a second power source VSS.

For example, the emission unit EMU may include the first connection electrode ELT1 connected to the first power source VDD through the pixel circuit PXC and a first power source line PL1, a fifth connection electrode ELT5 connected to the second power source VSS through a second power source line PL2, and light emitting elements LD connected between the first and fifth connection electrodes ELT1 and ELT5.

The first power source VDD and the second power source VSS may have different potentials so that the light emitting elements LD may emit light. As an example, the first power source VDD may be set as a high-potential power source, and the second power source VSS may be set as a low-potential power source.

In an embodiment, the emission unit EMU may include at least one series stage. Each series stage may include a pair of electrodes (for example, two electrodes) and at least one light emitting element LD connected in a forward-bias direction between the pair of electrodes. For example, the number of series stages constituting (or forming) the emission unit EMU and the number of light emitting elements LD constituting (or forming) each series stage are not limited. As an example, the number of light emitting elements LD constituting (or forming) each series stage may be the same or different, and the number of light emitting elements LD is not limited.

For example, the emission unit EMU may include a first series stage including at least one first light emitting element LD1, a second series stage including at least one second light emitting element LD2, a third series stage including at least one third light emitting element LD3, and a fourth series stage including at least one fourth light emitting element LD4.

The first series stage may include a first connection electrode ELT1, a second connection electrode ELT2, and at least one first light emitting element LD1 connected between the first and second connection electrodes ELT1 and ELT2. The first light emitting element LD1 may be connected in a forward-bias direction between the first and second connection electrodes ELT1 and ELT2. For example, a first end portion EP1 of the first light emitting element LD1 may be connected to the first connection electrode ELT1, and a second end portion EP2 of the first light emitting element LD1 may be connected to the second connection electrode ELT2.

The second series stage may include the second connection electrode ELT2, a third connection electrode ELT3, and at least one second light emitting element LD2 connected between the second and third connection electrodes ELT2 and ELT3. The second light emitting element LD2 may be connected in a forward-bias direction between the second and third connection electrodes ELT2 and ELT3. For example, a first end portion EP1 of the second light emitting element LD2 may be connected to the second connection electrode ELT2, and a second end portion EP2 of the second light emitting element LD2 may be connected to the third connection electrode ELT3.

The third series stage may include the third connection electrode ELT3, a fourth connection electrode ELT4, and at least one third light emitting element LD3 connected between the third and fourth connection electrodes ELT3 and ELT4. The third light emitting element LD3 may be connected in a forward-bias direction between the third and fourth connection electrodes ELT3 and ELT4. For example, a first end portion EP1 of the third light emitting element LD3 may be connected to the third connection electrode ELT3, and a second end portion EP2 of the third light emitting element LD3 may be connected to the fourth connection electrode ELT4.

The fourth series stage may include the fourth connection electrode ELT4, a fifth connection electrode ELT5, and at least one fourth light emitting element LD4 connected between the fourth and fifth connection electrodes ELT4 and ELT5. The fourth light emitting element LD4 may be connected in a forward-bias direction between the fourth and fifth connection electrodes ELT4 and ELT5. For example, a first end portion EP1 of the fourth light emitting element LD4 may be connected to the fourth connection electrode ELT4, and a second end portion EP2 of the fourth light emitting element LD4 may be connected to the fifth connection electrode ELT5.

A first electrode of the emission unit EMU, for example, the first connection electrode ELT1, may be an anode electrode of the emission unit EMU. The last electrode of the emission unit EMU, for example, the fifth connection electrode ELT5, may be a cathode electrode of the emission unit EMU.

The remaining electrodes of the emission unit EMU, for example, the second connection electrode ELT2, the third connection electrode ELT3, and/or the fourth connection electrode ELT4, may constitute (or form) intermediate electrodes. For example, the second connection electrode ELT2 may constitute (or form) a first intermediate electrode IET1, the third connection electrode ELT3 may constitute (or form) a second intermediate electrode IET2, and the fourth connection electrode ELT4 may constitute (or form) a third intermediate electrode IET3.

In case that light emitting elements LD are connected in a series/parallel structure, power efficiency may be improved compared to the case where the same number of light emitting elements LD are connected only in parallel. In a pixel PXL where light emitting elements LD are connected in a series/parallel structure, although a short circuit defect occurs in some of series stages, a certain luminance may be expressed through the light emitting elements LD of the remaining series stages. Therefore, the possibility of dark spot defects in the pixel PXL may be reduced. However, embodiments are not limited thereto, and the emission unit EMU may be formed by connecting light emitting elements LD only in series, or the emission unit EMU may be formed by connecting light emitting elements LD only in parallel.

Each of the light emitting elements LD may include a first end portion EP1 (for example, a p-type end portion) connected to the first power source VDD via at least one electrode (for example, the first connection electrode ELT1), the pixel circuit PXC, and/or the first power source line PL1, and a second end portion EP2 (for example, an n-type end portion) connected to the second power source VSS via at least one other electrode (for example, the fifth connection electrode ELT5) and the second power source line PL2. The light emitting elements LD may be connected in a forward-bias direction between the first power source VDD and the second power source VSS. The light emitting elements LD connected in the forward-bias direction may constitute (or form) effective light sources of the emission unit EMU.

In case that a driving current is supplied through a corresponding pixel circuit PXC, the light emitting elements LD may emit light with a luminance corresponding to the driving current. For example, during each frame period, the pixel circuit PXC may supply the driving current corresponding to a grayscale value to be expressed in the frame to the emission unit EMU. Accordingly, in case that the light emitting elements LD emit light with a luminance corresponding to the driving current, the emission unit EMU may express the luminance corresponding to the driving current.

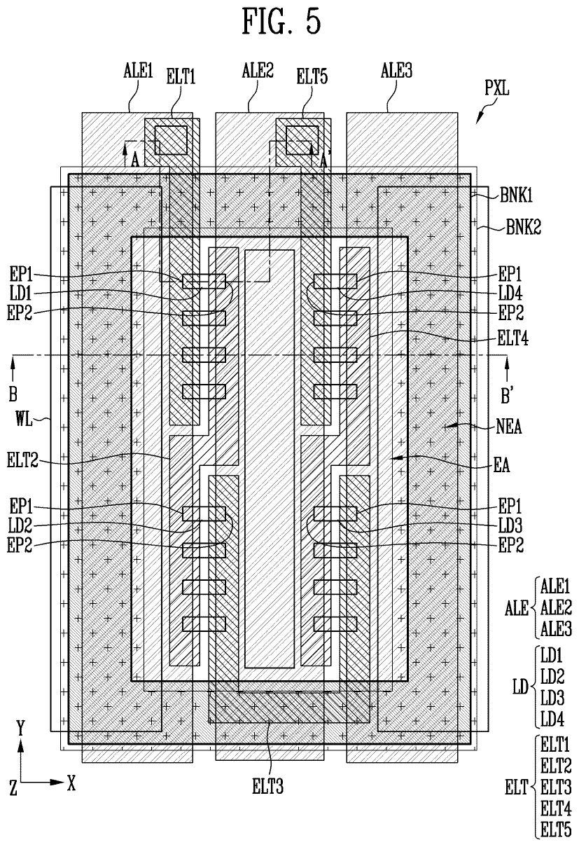

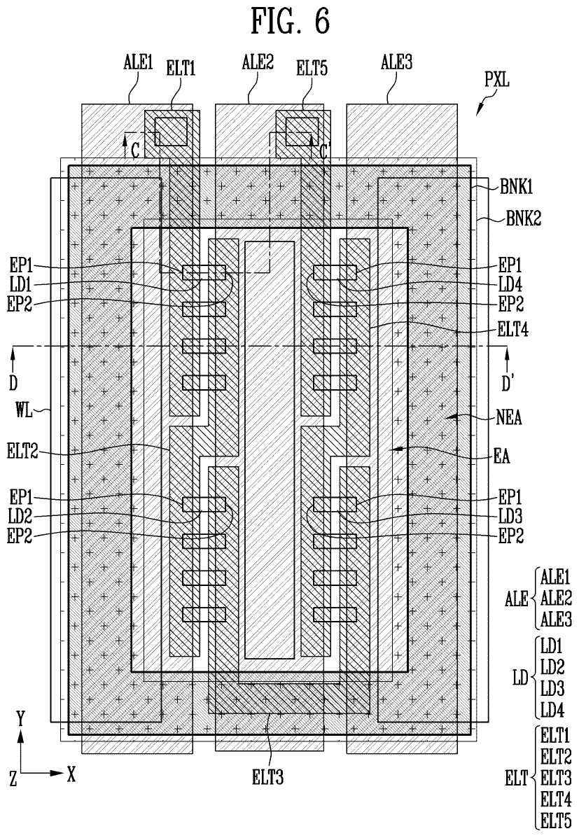

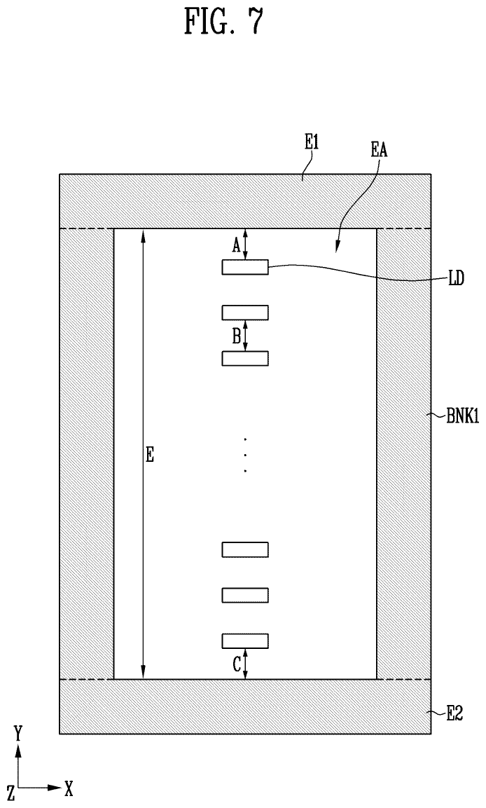

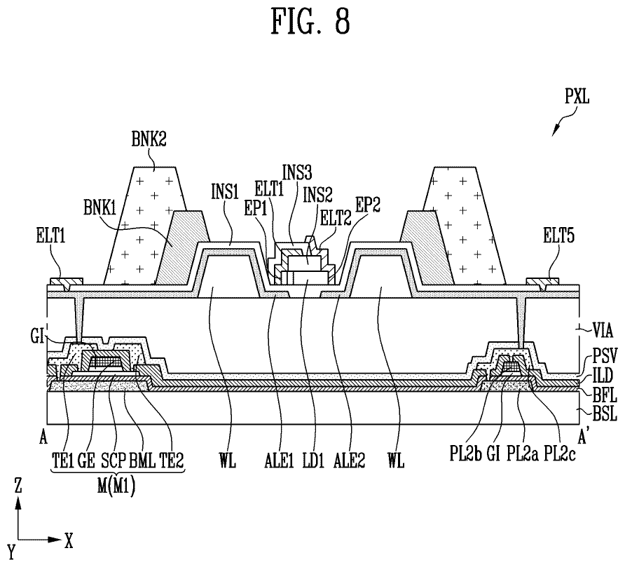

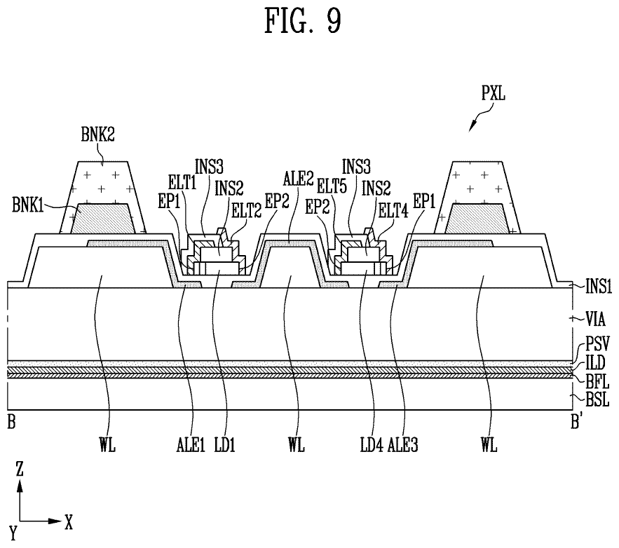

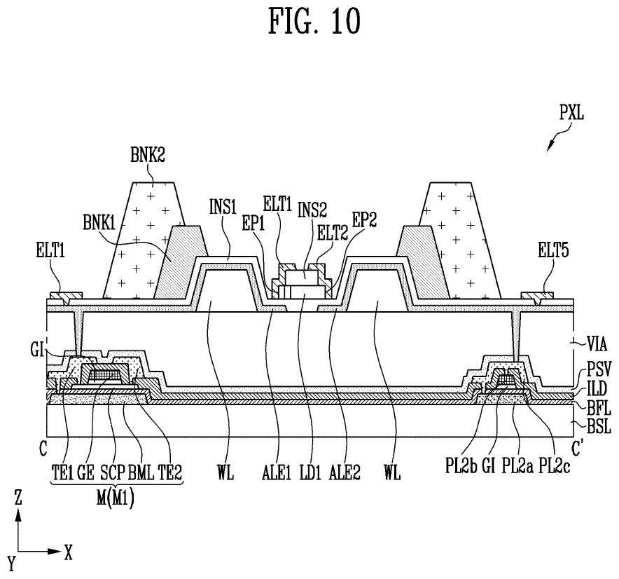

FIGS. 5 and 6 are schematic plan views illustrating pixels according to embodiments. FIG. 7 is a schematic plan view for explaining an arrangement of light emitting elements according to an embodiment. FIG. 8 is a schematic cross-sectional view taken along line A-A′ in FIG. 5. FIG. 9 is a cross-sectional view taken along line B-B′ in FIG. 5. FIG. 10 is a schematic cross-sectional view taken along line C-C′ in FIG. 6. FIG. 11 is a schematic cross-sectional view taken along line D-D′ in FIG. 6.

As an example, FIGS. 5 and 6 show one of the first to third pixels PXL1, PXL2, and PXL3 constituting (or forming) the pixel unit PXU of FIG. 3. The first to third pixels PXL1, PXL2, and PXL3 may have substantially the same or similar structures. FIGS. 5 and 6 show an embodiment in which each pixel PXL includes light emitting elements LD arranged in four series stages as shown in FIG. 4. However, the number of serial stages of each pixel PXL may vary according to embodiments.

Hereinafter, in case that one or more light emitting elements among the first to fourth light emitting elements LD1, LD2, LD3, and LD4 are arbitrarily referred to, or two or more types of light emitting elements are comprehensively referred to, they may be referred to as “light emitting element LD” or “light emitting elements LD”. In case that at least one electrode among electrodes including first to third electrodes ALE1, ALE2, and ALE3 is arbitrarily referred to, they may be referred to as “electrode ALE” or “electrodes ALE”. In case that at least one electrode among electrodes including the first to fifth connection electrodes ELT1, ELT2, ELT3, ELT4, and ELT5 is arbitrarily referring to, they may be referred to as “connection electrode ELT” or “connection electrodes ELT”.

Referring to FIGS. 5 and 6, the pixel PXL may include an emission area EA and a non-emission area NEA. The emission area EA may include light emitting elements LD and may be an area capable of emitting light. The non-emission area NEA may be disposed to surround the emission area EA. The non-emission area NEA may be an area in which a first bank BNK1 surrounding the emission area EA is disposed. The first bank BNK1 may be disposed in the non-emission area NEA and disposed to at least partially surround the emission area EA.

The first bank BNK1 may include an opening that overlaps the emission area EA. The opening of the first bank BNK1 may provide a space where the light emitting elements LD are provided (or disposed) in the step (or process) of supplying the light emitting elements LD to the pixels PXL. For example, a desired type and/or amount of light emitting element ink may be supplied to the space defined by the opening of the first bank BNK1.

The first bank BNK1 may include an organic material such as an acrylates resin, an epoxy resin, a phenolic resin, a polyamides resin, a polyimides resin, a polyesters resin, a polyphenylenesulfides resin, or benzocyclobutene (BCB). However, embodiments are not limited thereto, and the first bank BNK1 may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

According to an embodiment, the first bank BNK1 may include at least one light blocking and/or reflective material. Accordingly, light leakage between adjacent pixels PXL may be prevented. For example, the first bank BNK1 may include at least one black pigment.

A second bank BNK2 may include an opening that overlaps the emission area EA. The opening of the second bank BNK2 may provide a space where a color conversion layer, which will be described later, is provided. For example, a desired type and/or amount of color conversion layer may be supplied to the space defined by the opening of the second bank BNK2.

The second bank BNK2 may include an organic material such as an acrylates resin, an epoxy resin, a phenolic resin, a polyamides resin, a polyimides resin, a polyesters resin, a polyphenylenesulfides resin, or benzocyclobutene (BCB). However, embodiments are not limited thereto, and the second bank BNK2 may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

According to an embodiment, the second bank BNK2 may include at least one light blocking and/or reflective material. Accordingly, light leakage between adjacent pixels PXL may be prevented. For example, the second bank BNK2 may include at least one black pigment.

The pixel PXL may include walls (or partition walls) WL, electrodes ALE, light emitting elements LD, and/or connection electrodes ELT.

The walls WL may overlap the emission area EA and may be spaced apart from each other. The walls WL may be disposed at least partially in the non-emission area NEA. The walls WL may extend in a second direction (e.g., Y-axis direction) and may be spaced apart from each other in a first direction (e.g., X-axis direction).

Each of the walls WL may partially overlap at least one electrode ALE in the emission area EA. For example, the walls WL may be disposed below the electrodes ALE. As the walls WL are disposed below portions of the electrodes ALE, the portions of the electrodes ALE may protrude toward the top of the pixel PXL, e.g., in a third direction (e.g., Z-axis direction) in areas where the walls WL are formed. In case that the walls WL and/or the electrodes ALE include a reflective material, a reflective wall structure may be formed around the light emitting elements LD. Accordingly, light emitted from the light emitting elements LD may be emitted toward the top of the pixel PXL (for example, a front direction of the display panel PNL including a selected viewing angle range). Therefore, the light output efficiency of the display panel PNL may be improved.

The electrodes ALE may be disposed at least in the emission area EA. The electrodes ALE may extend in the second direction (e.g., Y-axis direction) and may be spaced apart from each other in the first direction (e.g., X-axis direction).

The first to third electrodes ALE1, ALE2, and ALE3 may extend in the second direction (e.g., Y-axis direction) and may be sequentially arranged to be spaced apart from each other in the first direction (e.g., X-axis direction). Some of the electrodes ALE may be connected to the pixel circuit PXC (shown in FIG. 4) and/or a selected power source line through a contact hole. For example, the first electrode ALE1 may be connected to the pixel circuit PXC and/or the first power source line PL1 through a contact hole, and the second electrode ALE2 may be connected to the second power source line PL2 through a contact hole.

According to an embodiment, some of the electrodes ALE may be electrically connected to some of the connection electrodes ELT through contact holes. For example, the first electrode ALE1 may be electrically connected to the first connection electrode ELT1 through a contact hole, and the second electrode ALE2 may be electrically connected to the fifth connection electrode ELT5 through a contact hole.

A pair of electrodes ALE adjacent to each other may receive different signals during the step (or process) of aligning the light emitting elements LD. For example, in case that the first to third electrodes ALE1, ALE2, and ALE3 are sequentially arranged in the first direction (e.g., X-axis direction), the first electrode ALE1 and the second electrode ALE2 may receive different alignment signals, and the second electrode ALE2 and the third electrode ALE3 may receive different alignment signals.

Each of the light emitting elements LD may be aligned between a pair of electrodes ALE in the emission area EA. Each of the light emitting elements LD may be electrically connected between a pair of connection electrodes ELT.

The first light emitting element LD1 may be aligned between the first and second electrodes ALE1 and ALE2. The first light emitting element LD1 may be electrically connected between the first and second connection electrodes ELT1 and ELT2. As an example, the first light emitting element LD1 may be aligned in first areas (for example, upper areas) of the first and second electrodes ALE1 and ALE2, the first end portion EP1 of the first light emitting element LD1 may be electrically connected to the first connection electrode ELT1, and the second end portion EP2 of the first light emitting element LD1 may be electrically connected to the second connection electrode ELT2.

The second light emitting element LD2 may be aligned between the first and second electrodes ALE1 and ALE2. The second light emitting element LD2 may be electrically connected between the second and third connection electrodes ELT2 and ELT3. As an example, the second light emitting element LD2 may be aligned in second areas (for example, lower areas) of the first and second electrodes ALE1 and ALE2, the first end portion EP1 of the second light emitting element LD2 may be electrically connected to the second connection electrode ELT2, and the second end portion EP2 of the second light emitting element LD2 may be electrically connected to the third connection electrode ELT3.

The third light emitting element LD3 may be aligned between the second and third electrodes ALE2 and ALE3. The third light emitting element LD3 may be electrically connected between the third and fourth connection electrodes ELT3 and ELT4. As an example, the third light emitting element LD3 may be aligned in second areas (for example, lower areas) of the second and third electrodes ALE2 and ALE3, the first end portion EP1 of the third light emitting element LD3 may be electrically connected to the third connection electrode ELT3, and the second end portion EP2 of the third light emitting element LD3 may be electrically connected to the fourth connection electrode ELT4.

The fourth light emitting element LD4 may be aligned between the second and third electrodes ALE2 and ALE3. The fourth light emitting element LD4 may be electrically connected between the fourth and fifth connection electrodes ELT4 and ELT5. As an example, the fourth light emitting element LD4 may be aligned in first areas (for example, upper areas) of the second and third electrodes ALE2 and ALE3, the first end portion EP1 of the fourth light emitting element LD4 may be electrically connected to the fourth connection electrode ELT4, and the second end portion EP2 of the fourth light emitting element LD4 may be electrically connected to the fifth connection electrode ELT5.

As an example, the first light emitting element LD1 may be positioned or disposed in an upper left area of the emission area EA, and the second light emitting element LD2 may be positioned or disposed in a lower left area of the emission area EA. The third light emitting element LD3 may be positioned or disposed in a lower right area of the emission area EA, and the fourth light emitting element LD4 may be positioned or disposed in an upper right area of the emission area EA. However, the arrangement and/or connection structure of the light emitting elements LD may vary according to the structure of the emission unit EMU and/or the number of series stages.

Each of the connection electrodes ELT may be disposed in the emission area EA and may be disposed to overlap at least one electrode ALE and/or light emitting element LD. For example, the connection electrodes ELT may be formed on the electrodes ALE and/or the light emitting elements LD to overlap the electrodes ALE and/or the light emitting elements LD and may be electrically connected to the light emitting elements LD.

The first connection electrode ELT1 may be disposed on a first area (for example, an upper area) of the first electrode ALE1 and first end portions EP1 of the first light emitting elements LD1 and electrically connected to the first end portions EP1 of the first light emitting elements LD1.

The second connection electrode ELT2 may be disposed on a first area (for example, an upper area) of the second electrode ALE2 and second end portions EP2 of the first light emitting elements LD1 and electrically connected to the second end portions EP2 of the first light emitting elements LD1. The second connection electrode ELT2 may be disposed on a second area (for example, a lower area) of the first electrode ALE1 and first end portions EP1 of the second light emitting elements LD2 and electrically connected to the first end portions EP1 of the second light emitting elements LD2. For example, the second connection electrode ELT2 may electrically connect the second end portions EP2 of the first light emitting elements LD1 and the first end portions EP1 of the second light emitting elements LD2 in the emission area EA. For example, the second connection electrode ELT2 may have a curved shape. For example, the second connection electrode ELT2 may have a structure that is bent or curved at the boundary between an area where at least one first light emitting element LD1 is arranged and an area where at least one second light emitting element LD2 is arranged.

The third connection electrode ELT3 may be disposed on a second area (for example, a lower area) of the second electrode ALE2 and second end portions EP2 of the second light emitting elements LD2 and electrically connected to the second end portions EP2 of the second light emitting elements LD2. The third connection electrode ELT3 may be disposed on a second area (for example, a lower area) of the third electrode ALE3 and first end portions EP1 of the third light emitting elements LD3 and electrically connected to the first end portions EP1 of the third light emitting elements LD3. For example, the third connection electrode ELT3 may electrically connect the second end portions EP2 of the second light emitting elements LD2 and the first end portions EP1 of the third light emitting elements LD3 in the emission area EA. For example, the third connection electrode ELT3 may have a curved shape. For example, the third connection electrode ELT3 may have a structure that is bent or curved at the boundary between an area where at least one second light emitting element LD2 is arranged and an area where at least one third light emitting element LD3 is arranged.

The fourth connection electrode ELT4 may be disposed on a second area (for example, a lower area) of the second electrode ALE2 and second end portions EP2 of the third light emitting elements LD3 and electrically connected to the second end portions EP2 of the third light emitting elements LD3. The fourth connection electrode ELT4 may be disposed on a first area (for example, an upper area) of the third electrode ALE3 and first end portions EP1 of the fourth light emitting elements LD4 and electrically connected to the first end portions EP1 of the fourth light emitting elements LD4. For example, the fourth connection electrode ELT4 may electrically connect the second end portions EP2 of the third light emitting elements LD3 and the first end portions EP1 of the fourth light emitting elements LD4 in the emission area EA. For example, the fourth connection electrode ELT4 may have a curved shape. For example, the fourth connection electrode ELT4 may have a structure that is bent or curved at the boundary between an area where at least one third light emitting element LD3 is arranged and an area where at least one fourth light emitting element LD4 is arranged.

The fifth connection electrode ELT5 may be disposed on a first area (for example, an upper area) of the second electrode ALE2 and second end portions EP2 of the fourth light emitting elements LD4 and electrically connected to the second end portions EP2 of the fourth light emitting elements LD4.

The first connection electrode ELT1, the third connection electrode ELT3, and/or the fifth connection electrode ELT5 may be made of the same conductive layer. The second connection electrode ELT2 and the fourth connection electrode ELT4 may be made of the same conductive layer. As an example, as shown in FIG. 9, the connection electrodes ELT may be composed of conductive layers. The first connection electrode ELT1, the third connection electrode ELT3, and/or the fifth connection electrode ELT5 may be made of a first conductive layer, and the second connection electrode ELT2 and the fourth connection electrode ELT4 may be made of a second conductive layer different from the first conductive layer. In another example, as shown in FIG. 10, the first to fifth connection electrodes ELT1, ELT2, ELT3, ELT4, and ELT5 may be made of the same conductive layer.

As described above, the light emitting elements LD aligned between the electrodes ALE may be connected in a desired form using the connection electrodes ELT. For example, the first light emitting elements LD1, the second light emitting elements LD2, the third light emitting elements LD3, and the fourth light emitting elements LD4 may be connected sequentially in series using the connection electrodes ELT.

Referring to FIG. 7, in case that a diameter D (shown in FIG. 1) of the light emitting element LD is α, a maximum distance B between the light emitting elements LD in the second direction (e.g., Y-axis direction) may be about 25α or less. In case that the maximum distance B between the light emitting elements LD in the second direction (e.g., Y-axis direction) exceeds about 25α, luminance dispersion may occur inside each of the pixels PXL and between the first pixel PXL1, the second pixel PXL2 and/or the third pixels PXL3. As an example, in case that the diameter D of the light emitting element LD is about 0.5 μm, the maximum distance B between the light emitting elements LD in the second direction (e.g., Y-axis direction) may be about 12.5 μm or less. In an embodiment, the maximum distance B between the light emitting elements LD in the second direction (e.g., Y-axis direction) may be about 4 μm or more. In case that the maximum distance B between the light emitting elements LD in the second direction (e.g., Y-axis direction) is less than about 4 μm, a phenomenon in which the light emitting elements LD clump together may occur.

A maximum distance between the light emitting element LD closest to the first bank BNK1 among the light emitting elements LD in the second direction (e.g., Y-axis direction) and the first bank BNK1 may be about 12.5α or less. In an embodiment, the first bank BNK1 may include a first extension E1 and a second extension E2. The first extension E1 and the second extension E2 may extend in the first direction (e.g., X-axis direction) and may be spaced apart from each other in the second direction (e.g., Y-axis direction).

A maximum distance A between the light emitting element LD closest to the first extension E1 among the light emitting elements LD in the second direction (e.g., Y-axis direction) and the first extension E1 may be about 12.5α or less. In case that the maximum distance A between the light emitting element LD closest to the first extension E1 among the light emitting elements LD in the second direction (e.g., Y-axis direction) and the first extension E1 exceeds about 12.5α, luminance dispersion may occur inside each of the pixels PXL and between the first pixel PXL1, the second pixel PXL2, and/or the third pixel PXL3. As an example, in case that the diameter D of the light emitting element LD is about 0.5 μm, the maximum distance A between the light emitting element LD closest to the first extension E1 among the light emitting elements LD in the second direction (e.g., Y-axis direction) and the first extension E1 may be about 6.3 μm or less.

A maximum distance C between the light emitting element LD closest to the second extension E2 among the light emitting elements LD in the second direction (e.g., Y-axis direction) and the second extension E2 may be the same as the maximum distance A between the light emitting element LD closest to the first extension E1 among the light emitting elements LD in the second direction (e.g., Y-axis direction) and the first extension E1. As an example, the maximum distance C between the light emitting element LD closest to the second extension E2 among the light emitting elements LD in the second direction (e.g., Y-axis direction) and the second extension E2 may be about 12.5α or less. In case that the maximum distance C between the light emitting element LD closest to the second extension E2 among the light emitting elements LD in the second direction (e.g., Y-axis direction) and the second extension E2 exceeds about 12.5α, luminance dispersion may occur inside each of the pixels PXL and between the first pixel PXL1, the second pixel PXL2, and/or the third pixel PXL3. In case that the diameter D of the light emitting element LD is about 0.5 μm, the maximum distance C between the light emitting element LD closest to the second extension E2 among the light emitting elements LD in the second direction (e.g., Y-axis direction) and the second extension E2 may be about 6.3 μm or less.

The maximum number of light emitting elements LD disposed in the emission area EA may satisfy Equation 1 below.

2γ+nα+(n−1)β=δ [Equation 1]

Where, α may be the diameter D of the light emitting element LD, β may be the maximum distance B between the light emitting elements LD in the second direction (e.g., Y-axis direction), γ may be the maximum distance between the light emitting element LD closest to the first bank BNK1 among the light emitting elements LD in the second direction (e.g., Y-axis direction) and the first bank BNK1, n may be the maximum number of light emitting elements LD disposed in the emission area EA, and δ may be a length E of the emission area EA in the second direction (e.g., Y-axis direction).

As described above, a may be about 0.5 μm or less, and β may be about 25% or less. In case that β exceeds about 25α, luminance dispersion may occur inside each of the pixels PXL and between the first pixel PXL1, the second pixel PXL2, and/or the third pixel PXL3, as described above. γ may be about 12.5 or less. In case that γ exceeds about 12.5α, luminance dispersion may occur inside each of the pixels PXL and between the first pixel PXL1, the second pixel PXL2, and/or the third pixel PXL3, as described above. δ may be determined according to the resolution of the display device.

According to the above-described embodiments, by deriving the maximum distance B between the light emitting elements LD and the maximum number of light emitting elements LD capable of minimizing the luminance dispersion of the pixels PXL, the display quality and reliability of the display device may be improved.

Hereinafter, a cross-sectional structure of the pixel PXL will be described in detail with reference to FIGS. 8 to 11. FIGS. 8 to 11 show the first transistor M1 among various circuit elements constituting (or forming) the pixel circuit PXC (shown in FIG. 4). If there is no need to separately specify the first to third transistors M1, M2, and M3, they will be comprehensively referred to as “transistor M”. For example, the structure and/or location of each layer of transistors M is not limited to the embodiments shown in FIGS. 8 and 10 and may vary according to embodiments.

The pixel PXL according to an embodiment may include circuit elements including transistors M disposed on the base layer BSL and various wirings connected thereto. The electrodes ALE, the light emitting elements LD, the connection electrodes ELT, the first bank BNK1, and/or the second bank BNK2 constituting (or forming) the emission unit EMU may be disposed on the circuit elements.

The base layer BSL may constitute (or form) a base member and may be a rigid or flexible substrate or a rigid or flexible film. As an example, the base layer BSL may be a rigid substrate made of glass or tempered glass, a flexible substrate (or thin film) made of plastic or metal, or at least one insulating layer. The material and/or physical properties of the base layer BSL are not limited. In an embodiment, the base layer BSL may be substantially transparent. For example, the term “substantially transparent” may mean that light may be transmitted above a selected transmittance. In other embodiments, the base layer BSL may be translucent or opaque. The base layer BSL may include a reflective material according to embodiments.

The lower conductive layer BML and a first power source conductive layer PL2a may be disposed on the base layer BSL. The lower conductive layer BML and the first power source conductive layer PL2a may be disposed on the same layer. For example, the lower conductive layer BML and the first power source conductive layer PL2a may be formed simultaneously in the same process or may be formed of a same material, but embodiments are not limited thereto. The first power source conductive layer PL2a may constitute (or form) the second power source line PL2 described with reference to FIG. 4 and the like.

Each of the lower conductive layer BML and the first power source conductive layer PL2a may be composed of a single layer or multiple layers made of molybdenum (Mo), copper (Cu), aluminum (Al), chromium (Cr), gold (Au), titanium (Ti), nickel (Ni), neodymium (Nd), indium (In), tin (Sn), and an oxide or alloy thereof.

A buffer layer BFL may be disposed on the lower conductive layer BML and the first power source conductive layer PL2a. The buffer layer BFL may prevent impurities from diffusing (or permeated) into the circuit elements. The buffer layer BFL may be composed of a single layer, but may also be composed of multiple layers, at least a double layer or more. In case that the buffer layer BFL is formed of multiple layers, each layer may be formed of the same material or may be formed of different materials.

A semiconductor pattern SCP may be disposed on the buffer layer BFL. As an example, the semiconductor pattern SCP may include a first region in contact with a first transistor electrode TE1, a second region in contact with a second transistor electrode TE2, and a channel region positioned or disposed between the first and second regions. According to an embodiment, one of the first and second regions may be a source region and the other may be a drain region.

According to an embodiment, the semiconductor pattern SCP may be made of polysilicon, amorphous silicon, oxide semiconductor, or the like. The channel region of the semiconductor pattern SCP may be a semiconductor pattern that is not doped with an impurity and may be an intrinsic semiconductor. The first and second regions of the semiconductor pattern SCP may be semiconductors doped with a selected impurity.

A gate insulating layer GI may be disposed on the buffer layer BFL and the semiconductor pattern SCP. As an example, the gate insulating layer GI may be disposed between the semiconductor pattern SCP and a gate electrode GE. The gate insulating layer GI may be disposed between the buffer layer BFL and a second power source conductive layer PL2b. The gate insulating layer GI may be composed of a single layer or multiple layers, and may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The gate electrode GE of the transistor M and the second power source conductive layer PL2b may be disposed on the gate insulating layer GI. The gate electrode GE and the second power source conductive layer PL2b may be disposed on the same layer. For example, the gate electrode GE and the second power source conductive layer PL2b may be formed simultaneously in the same process or may be formed of a same material, but embodiments are not limited thereto. The gate electrode GE may overlap the semiconductor pattern SCP in the third direction (e.g., Z-axis direction) on the gate insulating layer GI. The second power source conductive layer PL2b may overlap the first power source conductive layer PL2a in the third direction (e.g., Z-axis direction) on the gate insulating layer GI. The second power source conductive layer PL2b, together with the first power source conductive layer PL2a, may form the second power source line PL2 described with reference to FIG. 4 and the like.

Each of the gate electrode GE and the second power source conductive layer PL2b may be composed of a single layer or multiple layers made of molybdenum (Mo), copper (Cu), aluminum (Al), chromium (Cr), gold (Au), titanium (Ti), nickel (Ni), neodymium (Nd), indium (In), tin (Sn), and an oxide or alloy thereof. For example, each of the gate electrode GE and the second power source conductive layer PL2b may be composed of multiple layers of titanium (Ti), copper (Cu), and/or indium tin oxide (ITO) sequentially or repeatedly stacked.

An interlayer insulating layer ILD may be disposed on the gate electrode GE and the second power source conductive layer PL2b. As an example, the interlayer insulating layer ILD may be disposed between the gate electrode GE and the first and second transistor electrodes TE1 and TE2. The interlayer insulating layer ILD may be disposed between the second power source conductive layer PL2b and a third power source conductive layer PL2c.

The interlayer insulating layer ILD may be composed of a single layer or multiple layers, and may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The first and second transistor electrodes TE1 and TE2 of the transistor M and the third power source conductive layer PL2c may be disposed on the interlayer insulating layer ILD. The first and second transistor electrodes TE1 and TE2 and the third power source conductive layer PL2c may be disposed on the same layer. For example, the first and second transistor electrodes TE1 and TE2 and the third power source conductive layer PL2c may be formed simultaneously in the same process or may be formed of a same material, but embodiments are not limited thereto.

The first and second transistor electrodes TE1 and TE2 may overlap the semiconductor pattern SCP in the third direction (e.g., Z-axis direction). The first and second transistor electrodes TE1 and TE2 may be electrically connected to the semiconductor pattern SCP. For example, the first transistor electrode TE1 may be electrically connected to the first region of the semiconductor pattern SCP through a contact hole penetrating the interlayer insulating layer ILD. The first transistor electrode TE1 may be electrically connected to the lower conductive layer BML through a contact hole penetrating the interlayer insulating layer ILD and the buffer layer BFL. The second transistor electrode TE2 may be electrically connected to the second region of the semiconductor pattern SCP through a contact hole penetrating the interlayer insulating layer ILD. According to an embodiment, one of the first and second transistor electrodes TE1 and TE2 may be a source electrode, and the other may be a drain electrode.

The third power source conductive layer PL2c may overlap the first power source conductive layer PL2a and/or the second power source conductive layer PL2b in the third direction (e.g., Z-axis direction). The third power source conductive layer PL2c may be electrically connected to the first power source conductive layer PL2a and/or the second power source conductive layer PL2b. For example, the third power source conductive layer PL2c may be electrically connected to the first power source conductive layer PL2a through a contact hole penetrating the interlayer insulating layer ILD and the buffer layer BFL. The third power source conductive layer PL2c may be electrically connected to the second power source conductive layer PL2b through a contact hole penetrating the interlayer insulating layer ILD. The third power source conductive layer PL2c, together with the first power source conductive layer PL2a and/or the second power source conductive layer PL2b, may form the second power source line PL2 described with reference to FIG. 4 and the like.

The first and second transistor electrodes TE1 and TE2 and the third power source conductive layer PL2c may be composed of a single layer or multiple layers made of molybdenum (Mo), copper (Cu), aluminum (Al), chromium (Cr), gold (Au), titanium (Ti), nickel (Ni), neodymium (Nd), indium (In), tin (Sn), and an oxide or alloy thereof.

A passivation layer PSV may be disposed on the first and second transistor electrodes TE1 and TE2 and the third power source conductive layer PL2c. The passivation layer PSV may be composed of a single layer or multiple layers, and may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

A via layer VIA may be disposed on the passivation layer PSV. The via layer VIA may be made of an organic material to planarize a step difference below the via layer VIA. For example, the via layer VIA may include an organic material such as an acrylates resin, an epoxy resin, a phenolic resin, a polyamides resin, a polyimides resin, a polyesters resin, a polyphenylenesulfides resin, or benzocyclobutene (BCB). However, embodiments are not limited thereto, and the via layer VIA may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

Walls WL may be disposed on the via layer VIA. The walls WL may form selected step differences so that the light emitting elements LD may be readily aligned in the emission area EA.

The walls WL may have various shapes according to embodiments. In an embodiment, the walls WL may have a shape that protrudes from the base layer BSL in the third direction (e.g., Z-axis direction). The walls WL may be formed to have inclined surfaces inclined at a selected angle with respect to the base layer BSL. However, embodiments are not limited thereto, and the walls WL may have curved side surfaces or step-shaped side surfaces. As an example, the walls WL may have a semicircular or semielliptical cross section.

The walls WL may include at least one organic material and/or inorganic material. As an example, the walls WL may include an organic material such as an acrylates resin, an epoxy resin, a phenolic resin, a polyamides resin, a polyimides resin, a polyesters resin, a polyphenylenesulfides resin, or benzocyclobutene (BCB). However, embodiments are not limited thereto, and the walls WL may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The electrodes ALE may be disposed on the via layer VIA and the walls WL. The electrodes ALE may at least partially cover the sides and/or upper surfaces of the walls WL. The electrodes ALE disposed on the walls WL may have shapes corresponding to the walls WL. As an example, the electrodes ALE disposed on the walls WL may include inclined or curved surfaces having shapes corresponding to the shapes of the walls WL. For example, the walls WL and the electrodes ALE may be reflective members that reflect light emitted from the light emitting elements LD and guide the light toward the front of the pixel PXL, e.g., in the third direction (e.g., Z-axis direction). Therefore, the light output efficiency of the display panel PNL may be improved.

The electrodes ALE may be spaced apart from each other. The electrodes ALE may be disposed on the same layer. For example, the electrodes ALE may be formed simultaneously in the same process or may be formed of a same material, but embodiments are not limited thereto.

The electrodes ALE may receive an alignment signal in the step (or process) of aligning the light emitting elements LD. Accordingly, an electric field may be formed between the electrodes ALE so that the light emitting elements LD included in each pixel PXL may be aligned between the electrodes ALE.

The electrodes ALE may include at least one conductive material. As an example, the electrodes ALE may include at least one of various metal materials such as silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), or an alloy thereof, a conductive oxide such as indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO), or a conductive polymer such as poly(3,4-ethylenedioxythiophene) (PEDOT), but embodiments are not limited thereto.

The first electrode ALE1 may be electrically connected to the first transistor electrode TE1 of the transistor M through a contact hole penetrating the via layer VIA and the passivation layer PSV. The second electrode ALE2 may be electrically connected to the third power source conductive layer PL2c through a contact hole penetrating the via layer VIA and the passivation layer PSV.

A first insulating layer INS1 may be disposed on the electrodes ALE. The first insulating layer INS1 may be composed of a single layer or multiple layers, and may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The first bank BNK1 may be disposed on the first insulating layer INS1. The first bank BNK1 may include an opening that overlaps the emission area EA. The opening of the first bank BNK1 may provide a space where the light emitting elements LD are be formed in the step (or process) of supplying the light emitting elements LD to each pixel PXL. For example, a desired type and/or amount of light emitting element ink may be supplied to the space defined by the opening of the first bank BNK1.

The first bank BNK1 may include an organic material such as an acrylates resin, an epoxy resin, a phenolic resin, a polyamides resin, a polyimides resin, a polyesters resin, a polyphenylenesulfides resin, or benzocyclobutene (BCB). However, embodiments are not limited thereto, and the first bank BNK1 may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The light emitting elements LD may be disposed between the electrodes ALE. The light emitting elements LD may be bias-aligned between the electrodes ALE. As an example, the light emitting elements LD may be bias-aligned so that the first end portions EP1 (or first semiconductor layers) may face or overlap the first electrode ALE1, and the second end portions EP2 (or second semiconductor layers) may face or overlap the second electrode ALE2.

The light emitting elements LD may be disposed in the opening of the first bank BNK1 and disposed between the walls WL. The light emitting elements LD may be prepared (or provided) in a dispersed form in the light emitting element ink and supplied to each pixel PXL by an inkjet printing method or the like. As an example, the light emitting elements LD may be dispersed in a volatile solvent and disposed to each pixel PXL. Subsequently, in case that an alignment signal is supplied to the electrodes ALE, an electric field may be formed between the electrodes ALE so that the light emitting elements LD may be aligned between the electrodes ALE. After the light emitting elements LD are aligned, the light emitting elements LD may be stably arranged between the electrodes ALE by volatilizing the solvent or removing the solvent in another manner.

A second insulating layer INS2 may be disposed on the light emitting elements LD. For example, the second insulating layer INS2 may be partially disposed on the light emitting elements LD and may expose the first and second end portions EP1 and EP2 of the light emitting elements LD. In case that the second insulating layer INS2 is formed on the light emitting elements LD after the alignment of the light emitting elements LD is completed, the light emitting elements LD may be prevented from being separated from the aligned positions.

The second insulating layer INS2 may be composed of a single layer or multiple layers, and may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The connection electrodes ELT may be disposed on the first and second end portions EP1 and EP2 of the light emitting elements LD exposed by the second insulating layer INS2. The first connection electrode ELT1 may be disposed (e.g., directly disposed) on the first end portions EP1 of the first light emitting elements LD1, and may be in contact with the first end portions EP1 (or the first semiconductor layers) of the first light emitting elements LD1.

The second connection electrode ELT2 may be disposed (e.g., directly disposed) on the second end portions EP2 (or second semiconductor layers) of the first light emitting elements LD1 and may be in contact with the second end portions EP2 (or second semiconductor layers) of the first light emitting elements LD1. The second connection electrode ELT2 may be disposed (e.g., directly disposed) on the first end portions EP1 (or first semiconductor layers) of the second light emitting elements LD2, and may be in contact with the first end portions EP1 (or first semiconductor layers) of the second light emitting elements LD2. The second connection electrode ELT2 may electrically connect the second end portions EP2 (or second semiconductor layers) of the first light emitting elements LD1 and the first end portions EP1 (or first semiconductor layers) of the second light emitting elements LD2.

For example, the third connection electrode ELT3 may be disposed (e.g., directly disposed) on the second end portions EP2 (or second semiconductor layers) of the second light emitting elements LD2 and may be in contact with the second end portions EP2 (or second semiconductor layers) of the second light emitting elements LD2. The third connection electrode ELT3 may be disposed (e.g., directly disposed) on the first end portions EP1 (or first semiconductor layers) of the third light emitting elements LD3, and may be in connect with the first end portions EP1 (or first semiconductor layers) of the third light emitting elements LD3. The third connection electrode ELT3 may electrically connect the second end portions EP2 (or second semiconductor layers) of the second light emitting elements LD2 and the first end portions EP1 (or first semiconductor layers) of the third light emitting elements LD3.

For example, the fourth connection electrode ELT4 may be disposed (e.g., directly disposed) on the second end portions EP2 (or second semiconductor layers) of the third light emitting elements LD3 and may be in contact with the second end portions EP2 (or second semiconductor layers) of the third light emitting elements LD3. The fourth connection electrode ELT4 may be disposed (e.g., directly disposed) on the first end portions EP1 (or first semiconductor layers) of the fourth light emitting elements LD4, and may be in contact with the first end portions EP1 (or first semiconductor layers) of the fourth light emitting elements LD4. The fourth connection electrode ELT4 may electrically connect the second end portions EP2 (or second semiconductor layers) of the third light emitting elements LD3 and the first end portions EP1 (or first semiconductor layers) of the fourth light emitting elements LD4.

For example, the fifth connection electrode ELT5 may be disposed (e.g., directly disposed) on the second end portions EP2 (or second semiconductor layers) of the fourth light emitting elements LD4 and may be in contact with the second end portions EP2 (or second semiconductor layers) of the fourth light emitting elements LD4.

The first connection electrode ELT1 may be electrically connected to the first electrode ALE1 through a contact hole penetrating the first insulating layer INS1. The fifth connection electrode ELT5 may be electrically connected to the second electrode ALE2 through a contact hole penetrating the first insulating layer INS1.

In an embodiment, the connection electrodes ELT may be composed of conductive layers. For example, as shown in FIGS. 8 and 9, the first connection electrode ELT1, the third connection electrode ELT3, and the fifth connection electrode ELT5 may be disposed on the same layer. The second connection electrode ELT2 and the fourth connection electrode ELT4 may be disposed on the same layer. The first connection electrode ELT1, the third connection electrode ELT3, and the fifth connection electrode ELT5 may be disposed on the second insulating layer INS2. A third insulating layer INS3 may be disposed on the first connection electrode ELT1, the third connection electrode ELT3, and the fifth connection electrode ELT5. The second connection electrode ELT2 and the fourth connection electrode ELT4 may be disposed on the third insulating layer INS3.

In case that the third insulating layer INS3 is disposed between the connection electrodes ELT made of different conductive layers, the connection electrodes ELT may be stably separated by the third insulating layer INS3. Therefore, electrical stability between the first and second end portions EP1 and EP2 of the light emitting elements LD may be ensured or secured.

The third insulating layer INS3 may be composed of a single layer or multiple layers, and may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

In another embodiment, the connection electrodes ELT may be composed of the same conductive layer. For example, as shown in FIGS. 10 and 11, the first to fifth connection electrodes ELT1, ELT2, ELT3, ELT4, and ELT5 may be disposed on the same layer. As an example, the first to fifth connection electrodes ELT1, ELT2, ELT3, ELT4, and ELT5 may be formed simultaneously in the same process or may be formed of a same material. In case that the connection electrodes ELT are formed simultaneously, the number of masks may be reduced, and the manufacturing process may be simplified.

The connection electrodes ELT may be made of various transparent conductive materials. As an example, the connection electrodes ELT may include at least one of various transparent conductive materials such as indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO), and may be implemented as substantially transparent or translucent to satisfy a selected light transmittance. Accordingly, light emitted from the first and second end portions EP1 and EP2 of the light emitting elements LD may pass through the connection electrodes ELT and may be emitted to the outside of the display panel PNL.

The second bank BNK2 may be disposed on the first bank BNK1. The second bank BNK2 may be disposed in the non-emission area NEA.

The second bank BNK2 may include an opening that overlaps the emission area EA. The opening of the second bank BNK2 may provide a space where a color conversion layer, which will be described later, is provided. For example, a desired type and/or amount of color conversion layer may be supplied to the space defined by the opening of the second bank BNK2.

The second bank BNK2 may include an organic material such as an acrylates resin, an epoxy resin, a phenolic resin, a polyamides resin, a polyimides resin, a polyesters resin, a polyphenylenesulfides resin, or benzocyclobutene (BCB). However, embodiments are not limited thereto, and the second bank BNK2 may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

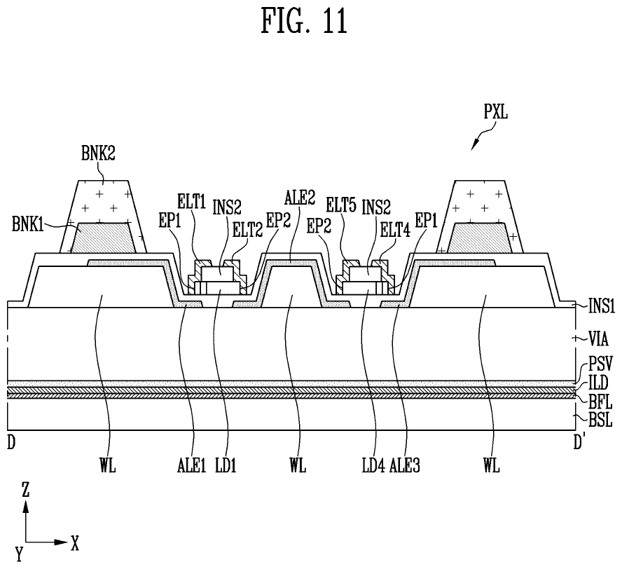

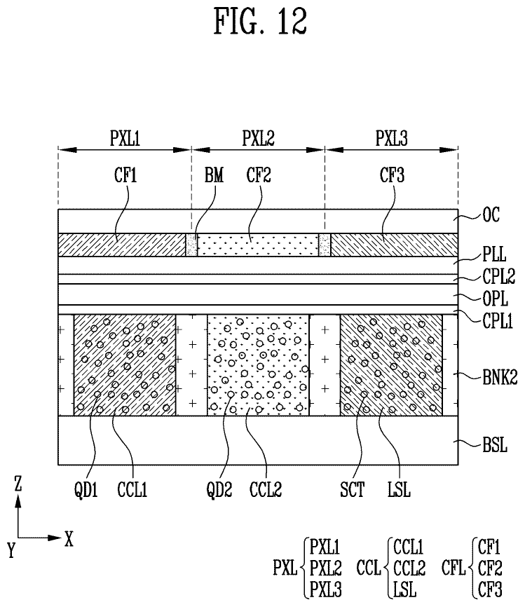

FIG. 12 is a schematic cross-sectional view illustrating first to third pixels according to an embodiment. FIG. 13 is a schematic cross-sectional view of a pixel according to an embodiment.

FIG. 12 shows a color conversion layer CCL, an optical layer OPL, and/or a color filter layer CFL. In FIG. 12, for convenience of description, components other than the base layer BSL and the second bank BNK2 of FIGS. 8 to 11 will be omitted. FIG. 12 shows a stacked structure of the pixel PXL in detail in relation to the color conversion layer CCL, the optical layer OPL, and/or the color filter layer CFL.

Referring to FIGS. 12 and 13, the second bank BNK2 may be disposed between or at the boundary of the first to third pixels PXL1, PXL2, and PXL3, and may include an opening that overlaps each of the first to third pixels PXL1, PXL2, and PXL3. The opening of the second bank BNK2 may provide a space where the color conversion layer CCL is formed.

The color conversion layer CCL may be disposed on the light emitting elements LD in the opening of the second bank BNK2. The color conversion layer CCL may include a first color conversion layer CCL1 disposed in the first pixel PXL1, a second color conversion layer CCL2 disposed in the second pixel PXL2, and a scattering layer LSL disposed in the third pixel PXL3.

In an embodiment, the first to third pixels PXL1, PXL2, and PXL3 may include the light emitting elements LD described in the embodiments of FIGS. 1 and 2. As an example, the first to third pixels PXL1, PXL2, and PXL3 may include light emitting elements LD that emit light of the same color, for example, the third color (or blue). A full-color image may be displayed by disposing the color conversion layer CCL including color conversion particles on each of the first to third pixels PXL1, PXL2, and PXL3.

The first color conversion layer CCL1 may include first color conversion particles that convert third color light emitted from the light emitting element LD into first color light. For example, the first color conversion layer CCL1 may include first quantum dots QD1 dispersed in a selected matrix material such as a base resin.

In an embodiment, in case that the light emitting element LD is a blue light emitting element that emits blue light and the first pixel PXL1 is a red pixel, the first color conversion layer CCL1 may include first quantum dots QD1 that convert the blue light emitted from the blue light emitting element into red light. The first quantum dots QD1 may absorb blue light, and emit red light by shifting the wavelength according to energy transition. In case that the first pixel PXL1 is a pixel of a different color, the first color conversion layer CCL1 may include first quantum dots QD1 corresponding to the color of the first pixel PXL1.

The second color conversion layer CCL2 may include second color conversion particles that convert third color light emitted from the light emitting element LD into second color light. For example, the second color conversion layer CCL2 may include second quantum dots QD2 dispersed in a selected matrix material such as a base resin.

In an embodiment, in case that the light emitting element LD is a blue light emitting element that emits blue light and the second pixel PXL2 is a green pixel, the second color conversion layer CCL2 may include second quantum dots QD2 that convert the blue light emitted from the blue light emitting element into green light. The second quantum dots QD2 may absorb blue light, and emit green light by shifting the wavelength according to energy transition. In case that the second pixel PXL2 is a pixel of a different color, the second color conversion layer CCL2 may include second quantum dots QD2 corresponding to the color of the second pixel PXL2.

In an embodiment, as blue light having a relatively short wavelength in the visible light region is incident on the first quantum dots QD1 and the second quantum dots QD2, respectively, the absorption coefficients of the first quantum dots QD1 and the second quantum dots QD2 may be increased. Accordingly, the efficiency of light finally emitted from the first pixel PXL1 and the second pixel PXL2 may be improved, and excellent color reproducibility may be ensured or secured. The manufacturing efficiency of the display device may be increased by configuring the emission units EMU of the first to third pixels PXL1, PXL2, and PXL3 using light emitting elements LD of the same color (for example, blue light emitting elements).

The scattering layer LSL may be provided to efficiently use the third color (or blue) light emitted from the light emitting element LD. As an example, in case that the light emitting element LD is a blue light emitting element that emits blue light and the third pixel PXL3 is a blue pixel, the scattering layer LSL may include at least one type of scatterers SCT to efficiently use the light emitted from the light emitting element LD. As an example, the scatterers SCT of the scattering layer LSL may include at least one of barium sulfate (BaSO₄), calcium carbonate (CaCO₃), titanium oxide (TiO₂), silicon oxide (SiO₂), aluminum oxide (Al₂O₃), zirconium oxide (ZrO₂), and zinc oxide (ZnO). For example, the scatterers SCT may not be disposed only in the third pixel PXL3, and may be selectively included in the first color conversion layer CCL1 or the second color conversion layer CCL2. In another example, the scatterers SCT may be omitted and the scattering layer LSL made of a transparent polymer may be formed.

A first capping layer CPL1 may be disposed on the color conversion layer CCL. The first capping layer CPL1 may be disposed across the first to third pixels PXL1, PXL2, and PXL3. The first capping layer CPL1 may cover the color conversion layer CCL. The first capping layer CPL1 may prevent impurities such as moisture or air from penetrating from the outside and damaging or contaminating the color conversion layer CCL.

The first capping layer CPL1 may be an inorganic layer and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), or the like.

The optical layer OPL may be disposed on the first capping layer CPL1. The optical layer OPL may function to improve light extraction efficiency by recycling light provided from the color conversion layer CCL through total reflection. For example, the optical layer OPL may have a relatively low refractive index compared to the color conversion layer CCL. For example, the refractive index of the color conversion layer CCL may be in a range of about 1.6 to about 2.0, and the refractive index of the optical layer OPL may be in a range of about 1.1 to about 1.3.

A second capping layer CPL2 may be disposed on the optical layer OPL. The second capping layer CPL2 may be disposed across the first to third pixels PXL1, PXL2, and PXL3. The second capping layer CPL2 may cover the optical layer OPL. The second capping layer CPL2 may prevent impurities such as moisture or air from penetrating from the outside and damaging or contaminating the optical layer OPL.

The second capping layer CPL2 may be an inorganic layer and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycabide (SiOₓC_{y}), silicon oxynitride (SiOₓN_{y}), or the like.

A planarization layer PLL may be disposed on the second capping layer CPL2. The planarization layer PLL may be disposed across the first to third pixels PXL1, PXL2, and PXL3.

The planarization layer PLL may include an organic material such as an acrylic resin, an epoxy resin, a phenolic resin, a polyamide resin, a polyimide resin, a polyester resin, a polyphenylenesulfide resin or benzocyclobutene (BCB). However, embodiments are not limited thereto, and the planarization layer PLL may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The color filter layer CFL may be disposed on the planarization layer PLL. The color filter layer CFL may include color filters CF1, CF2, and CF3 that match the colors of the pixels PXL. A full-color image may be displayed by disposing the color filters CF1, CF2, CF3 that match the colors of the first to third pixels PXL1, PXL2, and PXL3.

The color filter layer CFL may include a first color filter CF1 disposed in the first pixel PXL1 and selectively transmitting light emitted from the first pixel PXL1, a second color filter CF2 disposed in the second pixel PXL2 and selectively transmitting light emitted from the second pixel PXL2, and a third color filter CF3 disposed in the third pixel PXL3 and selectively transmitting light emitted from the third pixel PXL3.

In an embodiment, the first color filter CF1, the second color filter CF2, and the third color filter CF3 may be a red color filter, a green color filter, and a blue color filter, respectively, but embodiments are not limited thereto. Hereinafter, in case that any color filter among the first color filter CF1, the second color filter CF2, and the third color filter CF3 is arbitrarily referred to, or two or more types of color filters are comprehensively referred to, they may be referred to as “color filter CF” or “color filters CF”.

The first color filter CF1 may overlap the first color conversion layer CCL1 in the third direction (e.g., Z-axis direction). The first color filter CF1 may include a color filter material that selectively transmits light of the first color (or red). For example, in case that the first pixel PXL1 is a red pixel, the first color filter CF1 may include a red color filter material.

The second color filter CF2 may overlap the second color conversion layer CCL2 in the third direction (e.g., Z-axis direction). The second color filter CF2 may include a color filter material that selectively transmits light of the second color (or green). For example, in case that the second pixel PXL2 is a green pixel, the second color filter CF2 may include a green color filter material.

The third color filter CF3 may overlap the scattering layer LSL in the third direction (e.g., Z-axis direction). The third color filter CF3 may include a color filter material that selectively transmits light of the third color (or blue). For example, in case that the third pixel PXL3 is a blue pixel, the third color filter CF3 may include a blue color filter material.

According to an embodiment, a light blocking layer BM may be further disposed between the first to third color filters CF1, CF2, and CF3. In case that the light blocking layer BM is formed between the first to third color filters CF1, CF2, and CF3, color mixing defects visible from the front or side of the display device may be prevented. The material of the light blocking layer BM is not limited and various light blocking materials may be used. As an example, the light blocking layer BM may be implemented by stacking the first to third color filters CF1, CF2, and CF3.

An overcoat layer OC may be disposed on the color filter layer CFL. The overcoat layer OC may be disposed across the first to third pixels PXL1, PXL2, and PXL3. The overcoat layer OC may cover lower members including the color filter layer CFL. The overcoat layer OC may prevent moisture or air from penetrating into the lower members described above. The overcoat layer OC may protect the lower members described above from foreign substances such as dust.

The overcoat layer OC may include an organic material such as an acrylic resin, an epoxy resin, a phenolic resin, a polyamide resin, a polyimide resin, a polyester resin, a polyphenylenesulfide resin, or benzocyclobutene (BCB). However, embodiments are not limited thereto, and the overcoat layer OC may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

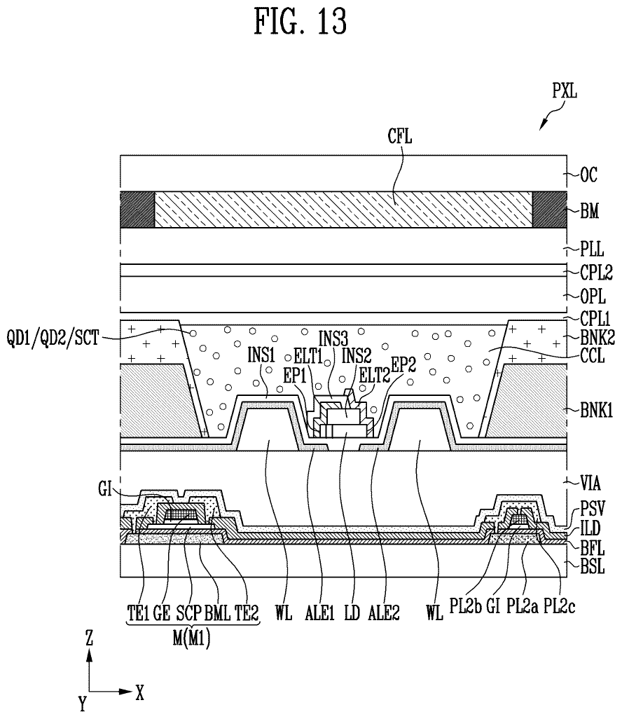

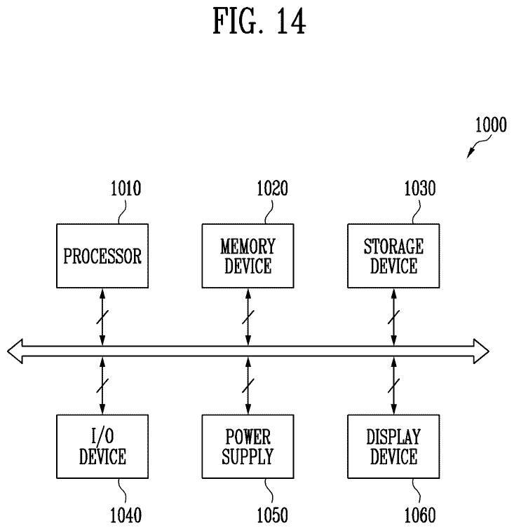

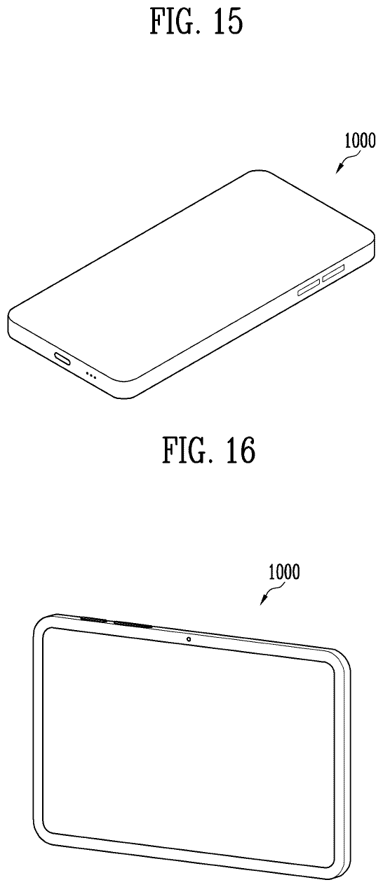

FIG. 14 is a schematic block diagram illustrating an electronic device 1000 including a display device in accordance with an embodiment. FIG. 15 is a schematic diagram illustrating an example where the electronic device 1000 of FIG. 14 is a smartphone. FIG. 16 is a schematic diagram illustrating an example where the electronic device 1000 of FIG. 14 is a tablet computer.

Referring to FIGS. 14 to 16, the electronic device 1000 may include a processor 1010, a memory device 1020, a storage device 1030, an input/output (I/O) device 1040, a power supply 1050, and a display device 1060. The display device 1060 may be the display device of FIG. 3. The electronic device 1000 may further include various ports for communication with a video card, a sound card, a memory card, a USB device, or other systems. In an embodiment, as illustrated in FIG. 15, the electronic device 1000 may be a smartphone. In an embodiment, as illustrated in FIG. 16, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

According to the embodiments, the display quality and reliability of a display device may be improved by deriving the maximum distance between light emitting elements and the maximum number of light emitting elements at which luminance dispersion of pixels may be minimized.

Effects according to the embodiments are not limited by the above-described contents, and more various other effects are included in the present specification.

Those skilled in the art related to the present embodiments will understand that the disclosure may be implemented in modified forms without departing from the essential features described above. Therefore, the methods described above should be considered from an illustrative rather than a restrictive perspective. The scope of the disclosure is indicated in the claims, not the foregoing description, and all differences in the equivalent scope should be construed as being included in the disclosure.

What is claimed is:

1. A display device comprising:
a bank surrounding an emission area;
a first electrode and a second electrode spaced apart from each other in the emission area; and
light emitting elements disposed between the first electrode and the second electrode,
wherein in case that a diameter of each of the light emitting elements is α, a maximum distance between the light emitting elements in a first direction is about 25α or less, and a maximum distance between a light emitting element closest to the bank among the light emitting elements in the first direction and the bank is about 12.5α or less.

2. The display device of claim 1, wherein the α is about 0.5 μm or less.

3. The display device of claim 1, wherein the maximum distance between the light emitting elements in the first direction is about 4 μm or more.

4. The display device of claim 1, wherein the bank extends in a second direction intersecting the first direction and includes a first extension and a second extension spaced apart from each other.

5. The display device of claim 4, wherein a maximum distance between a light emitting element closest to the first extension among the light emitting elements in the first direction and the first extension is about 12.5α or less.

6. The display device of claim 5, wherein a maximum distance between a light emitting element closest to the second extension among the light emitting elements in the first direction and the second extension is about 12.5α or less.

7. The display device of claim 1, wherein the first electrode and the second electrode are spaced apart from each other in a second direction intersecting the first direction.

8. The display device of claim 1, wherein
first end portions of the light emitting elements face the first electrode, and
second end portions of the light emitting elements face the second electrode.

9. The display device of claim 8, further comprising:
a first connection electrode and a second connection electrode disposed on the light emitting elements.

10. The display device of claim 9, wherein
the first connection electrode is electrically connected to the first end portions of the light emitting elements, and
the second connection electrode is electrically connected to the second end portions of the light emitting elements.

11. A display device comprising:
a bank surrounding an emission area;
a first electrode and a second electrode spaced apart from each other in the emission area; and
light emitting elements disposed between the first electrode and the second electrode,
wherein a maximum number of light emitting elements disposed in the emission area satisfies Equation 1 below,
2γ+nα+(n−1)β=δ [Equation 1]
where, α is a diameter of each of the light emitting elements, β is a maximum distance between the light emitting elements in a first direction, γ is a maximum distance between a light emitting element closest to the bank among the light emitting elements in the first direction and the bank, n is a maximum number of light emitting elements disposed in the emission area, and δ is a maximum length of the emission area in the first direction.

12. The display device of claim 11, wherein the β is about 25α or less.

13. The display device of claim 11, wherein the γ is about 12.5α or less.

14. The display device of claim 11, wherein the α is about 0.5 μm or less.

15. The display device of claim 11, wherein the β is about 4 μm or more.

16. The display device of claim 11, wherein the first electrode and the second electrode are spaced apart from each other in a second direction intersecting the first direction.

17. The display device of claim 11, wherein
first end portions of the light emitting elements face the first electrode, and
second end portions of the light emitting elements face the second electrode.

18. The display device of claim 17, further comprising:
a first connection electrode and a second connection electrode disposed on the light emitting elements.

19. The display device of claim 18, further comprising:
an insulating pattern disposed between the light emitting elements and the first connection electrode and/or the second connection electrode.

20. An electronic device comprising:
a processor to provide input image data; and
a display device to display an image based on the input image data, the display device including sub-pixel areas,
wherein the display device comprises:
a bank surrounding an emission area;
a first electrode and a second electrode spaced apart from each other in the emission area; and
light emitting elements disposed between the first electrode and the second electrode,
wherein in case that a diameter of each of the light emitting elements is α, a maximum distance between the light emitting elements in a first direction is about 25α or less, and a maximum distance between a light emitting element closest to the bank among the light emitting elements in the first direction and the bank is about 12.5α or less.
